(19) United States
(12) Patent Application Publication
(10) Pub. No.: US 2025/0203989 A1
(43) Pub. Date: Jun. 19, 2025

(54) SEMICONDUCTOR STRUCTURE WITH CONTACTS HAVING SIDEWALL SPACERS

(71) Applicant: International Business Machines Corporation, Armonk, NY (US)

(72) Inventors: Sagarika Mukesh, Albany, NY (US); Tao Li, Slingerlands, NY (US); Ruilong Xie, Niskayuna, NY (US); Nicolas Jean Loubet, Guilderland, NY (US)

(21) Appl. No.: 18/537,943

(22) Filed: Dec. 13, 2023

(51) Int. Cl. H01L 29/66; H01L 29/417

(52) U.S. Cl. CPC H10D 64/018; H10D 64/021; H10D 64/256

(57) ABSTRACT

A semiconductor structure includes a transistor at a first side of the semiconductor structure, a contact to the transistor at a second side of the semiconductor structure, and sidewall spacers surrounding a portion of sidewalls of the contact. The contact has a first width above the sidewall spacers and a second width below the sidewall spacers, the second width being different than the first width. The second width may be greater than the first width.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

A field-effect transistor (FET) is a three-terminal device having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the area of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm node and beyond. A general process flow for formation of a nanosheet stack involves removing sacrificial layers, which may be formed of Silicon Germanium (SiGe), between sheets of channel material, which may be formed of Silicon (Si).

### SUMMARY

Embodiments of the invention provide techniques for forming semiconductor structures having contacts with sidewall spacers, where the contacts have different widths above and below the sidewall spacers. The sidewall spacers advantageously enable preservation of placeholders during backside substrate etching processes.

In one embodiment, a semiconductor structure includes a transistor at a first side of the semiconductor structure, a contact to the transistor at a second side of the semiconductor structure, and sidewall spacers surrounding a portion of sidewalls of the contact. The contact has a first width above the sidewall spacers and a second width below the sidewall spacers, the second width being different than the first width.

The sidewall spacers of the semiconductor structure advantageously enable preservation of placeholders during backside substrate etching processes, where at least one of the placeholders is removed and replaced with the contact to the transistor at the second side of the semiconductor structure.

In another exemplary embodiment, as may be combined with the preceding paragraphs, the second width may be greater than the first width.

In another exemplary embodiment, as may be combined with the preceding paragraphs, the contact may have a third width between upper and lower surfaces of the sidewall spacers, the third width being different than the first width and the second width. The first width may be greater than the third width, and the second width may be greater than the first width.

In another exemplary embodiment, as may be combined with the preceding paragraphs, the contact may connect to a source/drain region of the transistor. The semiconductor structure may further include a placeholder at the second side of the semiconductor structure directly below another source/drain region of the transistor, and additional sidewall spacers surrounding a portion of sidewalls of the placeholder. The placeholder may have a third width above an upper surface of the additional sidewall spacers and a fourth width below the upper surface of the additional sidewall spacers, the third width being different than the fourth width. The fourth width may be greater than the third width. The additional sidewall spacers surrounding the portion of the sidewalls of the placeholder may be vertically aligned with the sidewall spacers surrounding the portion of the sidewalls of the contact.

In another exemplary embodiment, as may be combined with the preceding paragraphs, the semiconductor structure may further include an interlayer dielectric layer disposed between an upper surface of the sidewall spacers and a bottom dielectric insulator layer of the transistor.

In another embodiment, a semiconductor structure includes a transistor at a first side of the semiconductor structure, a placeholder self-aligned to a source/drain region of the transistor at a second side of the semiconductor structure, and sidewall spacers surrounding a portion of sidewalls of the placeholder. The placeholder has a first width above an upper surface of the sidewall spacers and a second width below the upper surface of the sidewall spacers, the second width being different than the first width.

The sidewall spacers of the semiconductor structure advantageously enable preservation of the placeholder during backside substrate etching processes.

In another exemplary embodiment, as may be combined with the preceding paragraphs, the second width may be greater than the first width.

In another exemplary embodiment, as may be combined with the preceding paragraphs, the semiconductor structure may further include a contact to another source/drain region of the transistor at the second side of the semiconductor structure and additional sidewall spacers surrounding a portion of sidewalls of the contact, where the contact has a third width above the additional sidewall spacers and a fourth width below the additional sidewall spacers, the third width being different than the fourth width. The fourth width may be greater than the third width.

In another embodiment, a semiconductor structure includes a transistor disposed at a first side of the semiconductor structure, a placeholder at a second side of the semiconductor structure, the placeholder being self-aligned to a first source/drain region of the transistor, a contact to a second source/drain region of the transistor at the second side of the semiconductor structure, and sidewall spacers surrounding portions of sidewalls of the placeholder and the contact. A first portion of the placeholder above an upper surface of the sidewall spacers has a different width than a second portion of the placeholder below the upper surface of the sidewall spacers. A first portion of the contact above the upper surface of the sidewall spacers has a different width than a second portion of the contact below a lower surface of the sidewall spacers.

In another exemplary embodiment, as may be combined with the preceding paragraphs, the first portion of the placeholder above the upper surface of the sidewall spacers may have a smaller width than the second portion of the placeholder below the upper surface of the sidewall spacers.

In another exemplary embodiment, as may be combined with the preceding paragraphs, the first portion of the contact above the upper surface of the sidewall spacers may have a smaller width than the second portion of the contact below the lower surface of the sidewall spacers. A third portion of the contact between the upper and lower surfaces of the sidewall spacers may have a different width than the first portion of the contact above the upper surface of the sidewall spacers and the second portion of the contact below the lower surface of the sidewall spacers.

In another exemplary embodiment, as may be combined with the preceding paragraphs, the upper surface of the sidewall spacers may be separated from a bottom dielectric insulator layer of the transistor by an interlayer dielectric layer.

In another embodiment, a transistor structure includes a first source/drain region, a second source/drain region, a placeholder self-aligned to a backside of the first source/drain region, a contact to a backside of the second source/drain region, and sidewall spacers surrounding portions of sidewalls of the placeholder and the contact. A first portion of the placeholder above an upper surface of the sidewall spacers has a different width than a second width of the placeholder below the upper surface of the sidewall spacers. A first portion of the contact above the upper surface of the sidewall spacers has a different width than a second portion of the contact below a lower surface of the sidewall spacers.

The sidewall spacers of the transistor structure advantageously enable preservation of placeholders, including the placeholder which is self-aligned to the backside of the first source/drain region, during backside substrate etching processes. At least one other placeholder may be removed and replaced with the contact to the backside of the second source/drain region.

In another exemplary embodiment, as may be combined with the preceding paragraphs, the first portion of the placeholder above the upper surface of the sidewall spacers may have a smaller width than the second portion of the placeholder below the upper surface of the sidewall spacers.

In another exemplary embodiment, as may be combined with the preceding paragraphs, the first portion of the contact above the upper surface of the sidewall spacers may have a smaller width than the second portion of the contact below the lower surface of the sidewall spacers.

In another exemplary embodiment, as may be combined with the preceding paragraphs, the upper surface of the sidewall spacers may be separated from a bottom dielectric insulator layer of the transistor structure by an interlayer dielectric layer.

In another embodiment, an integrated circuit includes a semiconductor structure including a transistor at a first side of the semiconductor structure, a contact to the transistor at a second side of the semiconductor structure, and sidewall spacers surrounding a portion of sidewalls of the contact. The contact has a first width above the sidewall spacers and a second width below the sidewall spacers, the second width being different than the first width.

The sidewall spacers of the semiconductor structure advantageously enable preservation of placeholders during backside substrate etching processes, where at least one of the placeholders is removed and replaced with the contact to the transistor at the second side of the semiconductor structure.

In another exemplary embodiment, as may be combined with the preceding paragraphs, the second width may be greater than the first width.

In another exemplary embodiment, as may be combined with the preceding paragraphs, the contact may connect to a source/drain region of the transistor. The semiconductor structure may further include a placeholder at the second side of the semiconductor structure directly below another source/drain region of the transistor and additional sidewall spacers surrounding a portion of sidewalls of the placeholder, where the placeholder has a third width above an upper surface of the additional sidewall spacers and a fourth width below the upper surface of the additional sidewall spacers, the third width being different than the fourth width.

### BRIEF DESCRIPTION OF THE DRAWINGS

FIG. 1A depicts a first cross-sectional view of a semiconductor structure following patterning of a nanosheet stack, formation of shallow trench isolation regions, formation and patterning of dummy gate structures, formation of gate spacers and a bottom dielectric insulator, nanosheet recess, indent of sacrificial layers of the nanosheet stack, and formation of inner spacers, according to an embodiment of the invention.

FIG. 1B depicts a second cross-sectional view of the semiconductor structure following the patterning of the nanosheet stack, the formation of the shallow trench isolation regions, the formation and patterning of the dummy gate structures, the formation of the gate spacers and the bottom dielectric insulator, the nanosheet recess, the indent of the sacrificial layers of the nanosheet stack, and the formation of the inner spacers, according to an embodiment of the invention.

FIG. 1C depicts a top-down view showing where the first and second cross-sectional views of FIGS. 1A and 1B are taken, according to an embodiment of the invention.

FIG. 2A depicts a first cross-sectional view of the structure of FIGS. 1A-1C following formation of a protection liner and placeholder cavity trenches, according to an embodiment of the invention.

FIG. 2B depicts a second cross-sectional view of the structure of FIGS. 1A-1C following the formation of the protection liner and the placeholder cavity trenches, according to an embodiment of the invention.

FIG. 3A depicts a first cross-sectional view of the structure of FIGS. 2A and 2B following a lateral etch of an etch stop layer and formation of placeholder sidewall spacers, according to an embodiment of the invention.

FIG. 3B depicts a second cross-sectional view of the structure of FIGS. 2A and 2B following the lateral etch of the etch stop layer and the formation of the placeholder sidewall spacers, according to an embodiment of the invention.

FIG. 4A depicts a first cross-sectional view of the structure of FIGS. 3A and 3B following formation of placeholders, removal of the protection liner and formation of source/drain regions, according to an embodiment of the invention.

FIG. 4B depicts a second cross-sectional view of the structure of FIGS. 3A and 3B following the formation of the placeholders, the removal of the protection liner, and the formation of the source/drain regions, according to an embodiment of the invention.

FIG. 5A depicts a first cross-sectional view of the structure of FIGS. 4A and 4B following formation of gate structures, an interlayer dielectric layer, middle-of-line contacts and back-end-of-line interconnects, and following bonding to a carrier wafer, according to an embodiment of the invention.

FIG. 5B depicts a second cross-sectional view of the structure of FIGS. 4A and 4B following the formation of the gate structures, the interlayer dielectric layer, the middle-of-line contacts and the back-end-of-line interconnects, and following the bonding to the carrier wafer, according to an embodiment of the invention.

FIG. 6A depicts a first cross-sectional view of the structure of FIGS. 5A and 5B following a wafer flip and substrate removal stopping on the etch stop layer, according to an embodiment of the invention.

FIG. 6B depicts a second cross-sectional view of the structure of FIGS. 5A and 5B following the wafer flip and the substrate removal stopping on the etch stop layer, according to an embodiment of the invention.

FIG. 7A depicts a first cross-sectional view of the structure of FIGS. 6A and 6B following a directional etch which removes the etch stop layer and portions of the placeholders, according to an embodiment of the invention.

FIG. 7B depicts a second cross-sectional view of the structure of FIGS. 6A and 6B following the directional etch which removes the etch stop layer and portions of the placeholders, according to an embodiment of the invention.

FIG. 8A depicts a first cross-sectional view of the structure of FIGS. 7A and 7B following removal of a remainder of the substrate, according to an embodiment of the invention.

FIG. 8B depicts a second cross-sectional view of the structure of FIGS. 7A and 7B following the removal of the remainder of the substrate, according to an embodiment of the invention.

FIG. 9A depicts a first cross-sectional view of the structure of FIGS. 8A and 8B following formation of a backside interlayer dielectric layer, according to an embodiment of the invention.

FIG. 9B depicts a second cross-sectional view of the structure of FIGS. 8A and 8B following the formation of the backside interlayer dielectric layer, according to an embodiment of the invention.

FIG. 10A depicts a first cross-sectional view of the structure of FIGS. 9A and 9B following formation and patterning of an organic planarization layer, and following formation of backside contact trenches, according to an embodiment of the invention.

FIG. 10B depicts a second cross-sectional view of the structure of FIGS. 9A and 9B following the formation and patterning of the organic planarization layer, and following the formation of the backside contact trenches, according to an embodiment of the invention.

FIG. 11A depicts a first cross-sectional view of the structure of FIGS. 10A and 10B following removal of ones of the placeholders exposed by the backside contact trenches, according to an embodiment of the invention.

FIG. 11B depicts a second cross-sectional view of the structure of FIGS. 10A and 10B following the removal of ones of the placeholders exposed by the backside contact trenches, according to an embodiment of the invention.

FIG. 12A depicts a first cross-sectional view of the structure of FIGS. 11A and 11B following formation of backside contacts and a backside power delivery network, according to an embodiment of the invention.

FIG. 12B depicts a second cross-sectional view of the structure of FIGS. 11A and 11B following the formation of the backside contacts and the backside power delivery network, according to an embodiment of the invention.

FIG. 13 shows an integrated circuit comprising one or more semiconductor structures with contacts having sidewall spacers, according to an embodiment of the invention.

### DETAILED DESCRIPTION

Illustrative embodiments of the invention may be described herein in the context of illustrative methods for forming semiconductor structures having contacts with sidewall spacers, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

Various semiconductor structures utilize backside contacts. Backside contact patterning may utilize placeholders formed in a substrate of the semiconductor structures, where backside processing involves patterning a mask over the backside of the structure in order to selectively remove placeholders where backside contacts are to be formed to portions of devices (e.g., transistors) formed in the frontside of the semiconductor structure. Backside contact patterning, however, may present overlay issues which result in opening and at least partial removal of placeholders which are not desired to be removed. This is exacerbated as, following substrate removal from the backside, the placeholder size becomes smaller especially at tapered areas. Thus, there may be unwanted placeholder loss during backside contact patterning.

Illustrative embodiments provide techniques for forming sidewall spacers on placeholders. Such sidewall spacers are advantageously better able to preserve the placeholders during backside substrate removal. The sidewall spacers also advantageously provide a backside contact etch stop (e.g., a reactive-ion etching (RIE) etch stop) and mitigate backside contact patterning overlay concerns. Thus, the techniques described herein can alleviate concerns of placeholder etch-out and allow for greater process margin for self-aligned backside contact formation.

In some embodiments, a semiconductor structure includes a pair of spacers on sidewalls of a backside contact. The semiconductor structure may also include a pair of spacers on sidewalls of a lower portion of a placeholder. The backside contact may be formed to contact a source/drain region of a transistor device. The placeholder may also be formed underneath a source/drain region of the transistor device. The backside contact may have a first width above the pair of spacers (e.g., proximate the source/drain region of the transistor device) and a second width below the pair of spacers (e.g., proximate a backside power delivery network (BSPDN)). The first width may be less than the second width. The pair of spacers may have a top or upper surface which is separated from a bottom dielectric insulator (BDI) by a backside interlayer dielectric (ILD) layer.

A method for forming a semiconductor structure may include patterning a nanosheet stack formed over a substrate, the substrate having an etch stop layer disposed therein. The nanosheet stack includes a first sacrificial layer and then alternating second sacrificial layers and nanosheet channel layers. The first and second sacrificial layers are configured for removal selective to one another and the nanosheet channel layers. For example, the first and second sacrificial layers may comprise silicon germanium (SiGe) with different percentages of germanium (Ge), and the nanosheet channel layers may comprise silicon (Si). Dummy gate structures are then formed and patterned over the nanosheet stack, followed by removal of the first sacrificial layer and formation of a spacer material providing a BDI (e.g., in the space formed by removal of the first sacrificial layer) and gate spacers on sidewalls of the dummy gate structures. The nanosheet stack may then be recessed, followed by indentation of the second sacrificial layers in the nanosheet stack and formation of inner spacers in the indent etch regions. A protection liner (e.g., formed of silicon nitride (SiN) or another suitable material) is then formed on sidewalls of the nanosheet stack and dummy gate structures above the BDI. The BDI is then opened, followed by etching into the substrate to form placeholder cavities. The substrate is etched through the etch stop layer and into a portion of the substrate below the etch stop layer. A lateral etch (e.g., an indent etch) of the etch stop layer is then performed, followed by fill of inner spacers in the indents of the etch stop layer. Placeholders (e.g., SiGe/Si) are then formed in the placeholder cavities. The protection liner may then be stripped, followed by growth of source/drain regions over the placeholders. Gate structures may then be formed using replacement metal gate (RMG) processing, and then middle-of-line (MOL) contacts and a back-end-of-line (BEOL) interconnect structure are formed. The structure is then bonded to a carrier wafer, followed by a wafer flip and removal of the substrate stopping on the etch stop layer. A directional etch is then performed (e.g., which removes the etch stop layer and portions of the placeholders). The remaining substrate is then removed, followed by fill and planarization (e.g., using chemical mechanical planarization (CMP) of a backside ILD layer. Backside contact patterning is then performed, where the inner spacers on the sides of the placeholders provide an etch stop for the backside contact patterning. The placeholders are then removed, followed by backside contact metallization and formation of a BSPDN.

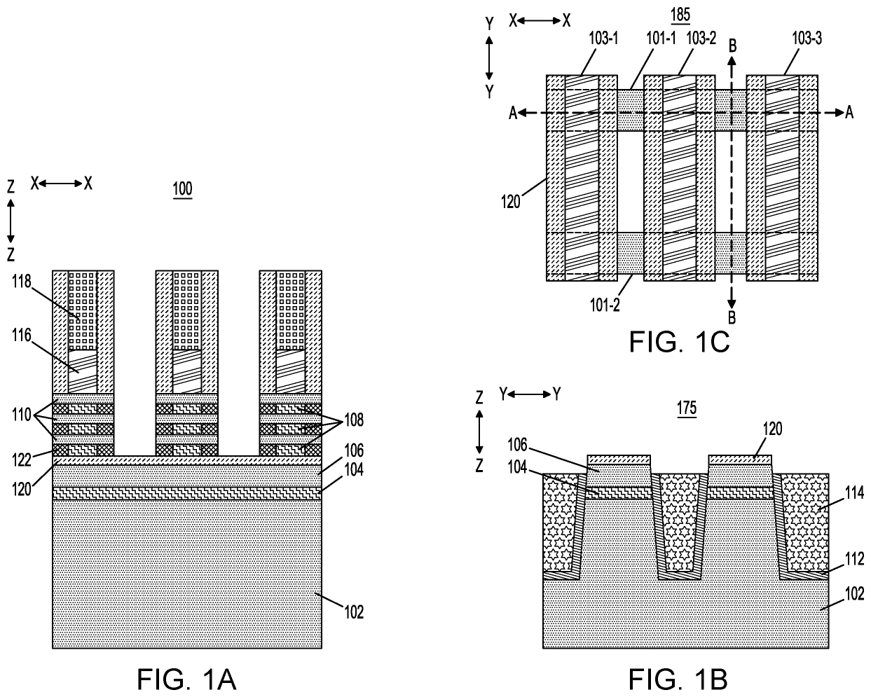

FIGS. 1A-12B show a process flow for forming sidewall spacers for placeholders, enabling better placeholder retention and backside contact position control.

FIGS. 1A-1C show different views of a semiconductor structure. FIG. 1A shows a first cross-sectional view 100 of the semiconductor structure, and FIG. 1B shows a second cross-sectional view 175 of the semiconductor structure. FIG. 1C shows a top-down view 185 illustrating where the first cross-sectional view 100 of FIG. 1A and the second cross-sectional view 175 of FIG. 1B are taken. FIG. 1C shows active regions 101-1 and 101-2 (collectively, active regions 101) and gate regions 103-1, 103-2 and 103-3 (collectively, gate regions 103). FIG. 1C also shows spacer layer 120. The first cross-sectional view 100 of FIG. 1A is taken along the line A-A shown in the top-down view 185 of FIG. 1C (e.g., along the active region 101-1 and across the gate regions 103). The second cross-sectional view 175 of FIG. 1B is taken along the line B-B shown in the top-down view 185 of FIG. 1C (e.g., between the gate regions 103-2 and 103-3 and across the active regions 101).

The semiconductor structure of FIGS. 1A-1C includes a substrate 102, an etch stop layer 104, a substrate 106, a nanosheet stack including alternating sacrificial layers 108 and nanosheet channel layers 110, a dielectric layer 112, shallow trench isolation (STI) regions 114, a dummy gate layer 116, a hard mask layer 118, the spacer layer 120, and inner spacers 122.

The substrates 102 and 106 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. The substrates 102 and 106 may have heights (in direction Z) and widths (in directions X/Y) which vary as needed based on the type of structures to be formed.

The etch stop layer 104 may comprise a buried oxide (BOX) layer or silicon germanium (SiGe), or another suitable material such as a III-V semiconductor epitaxial layer. The etch stop layer 104 may have a height (in direction Z) in the range of 10 to 30 nm.

The sacrificial layers 108 may be formed of SiGe. Each of the sacrificial layers 108 may have a thickness (in direction Z) in the range of 5-15 nm.

The nanosheet channel layers 110 will provide channels for transistors in a transistor structure. The nanosheet channel layers 110 may be formed of Si or another suitable material (e.g., a material similar to that used for the substrate 102). Each of the nanosheet channel layers 110 may have a thickness (in direction Z) in the range of 5-15 nm.

The dielectric layer 112 may be formed of a suitable dielectric material such as silicon nitride (SiN). The dielectric layer 112 may have a thickness in the range of 5-8 nm.

The STI regions 114 may be formed of a dielectric material such as silicon dioxide (SiO₂), silicon oxycarbide (SiOC), silicon oxynitride (SiON), etc. The STI regions 114 may have a height (in direction Z) in the range of 10 to 200 nm.

The dummy gate layer 116 may be formed of amorphous silicon (a-Si), amorphous silicon germanium (a-SiGe) over a thin SiO₂ or titanium nitride (TiN) layer, or another suitable material.

The hard mask layer 118 may be formed of silicon nitride (SiN), a multi-layer of SiN and SiO₂, or another suitable material. The hard mask layer 118 may have a height (in direction Z) in the range of 10 nm or larger, and a width (in direction X) matching that of the underlying dummy gate layer 116 (e.g., which may be patterned to have a width in the range of 10-10 nnm).

The spacer layer 120 may be formed of silicon boron carbide nitride (SiBCN) or another suitable material such as SiN, SiOC, silicon oxycarbonitride (SiOCN), etc. The spacer layer 120 may have a thickness in the range of 4 to 10 nm. The portions of the spacer layer 120 on sidewalls of the dummy gate layer 116 and the hard mask layer 118 provide gate spacers, while the portions of the spacer layer 120 between the substrate 106 and the nanosheet stack provides a bottom dielectric insulator (BDI) layer.

The inner spacers 122 may be formed of SiN, SiBCN, SiOCN, SiC, SiOC, or another suitable material.

The semiconductor structure of FIGS. 1A-1C may be formed by depositing the nanosheet stack (e.g., the sacrificial layers 108 and the nanosheet channel layers 110) over the substrate 106. The nanosheet stack may then be patterned (e.g., using lithographic processing), followed by deposition of the dielectric layer 112 and fill with material of the STI regions 114 and recess of the material of the STI regions 114. The dummy gate layer 116 is then patterned using the hard mask layer 118, followed by an etch that removes a sacrificial layer (not shown, but which may be formed of SiGe with a different percentage of Ge than the sacrificial layers 108) in the area where the BDI layer is shown. The spacer layer 120 is then formed, to provide the gate spacers and the BDI layer. An indent etch is then performed to indent the sacrificial layers 108. The inner spacers 122 are then formed. The depth of the indent etch (in direction X) may be in the range of 5-9 nm.

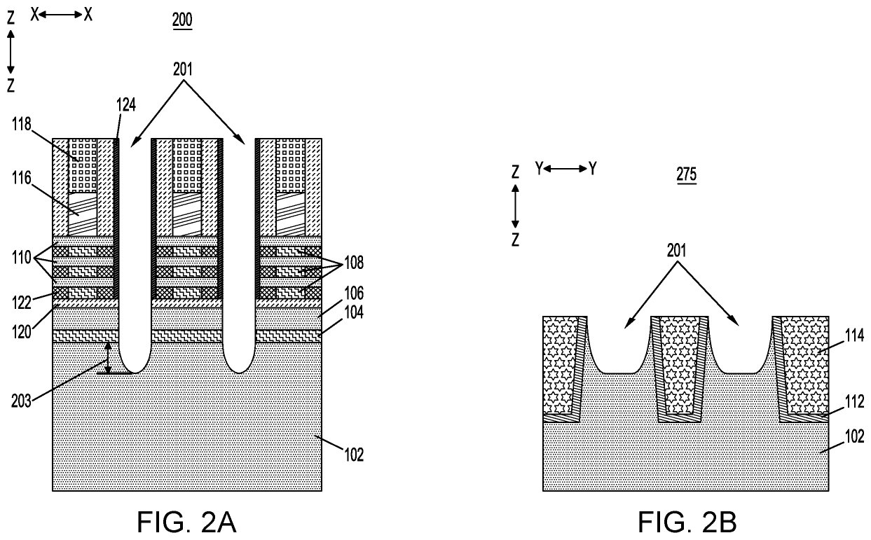

FIGS. 2A and 2B show first and second cross-sectional views 200 and 275, respectively, of the structure of FIGS. 1A-1C following formation of a protection liner 124 and placeholder cavity trenches 201. The first cross-sectional view 200 of FIG. 2A is taken along the line A-A shown in the top-down view 185 of FIG. 1C, and the second cross-sectional view 275 of FIG. 2B is taken along the line B-B shown in the top-down view 185 of FIG. 1C.

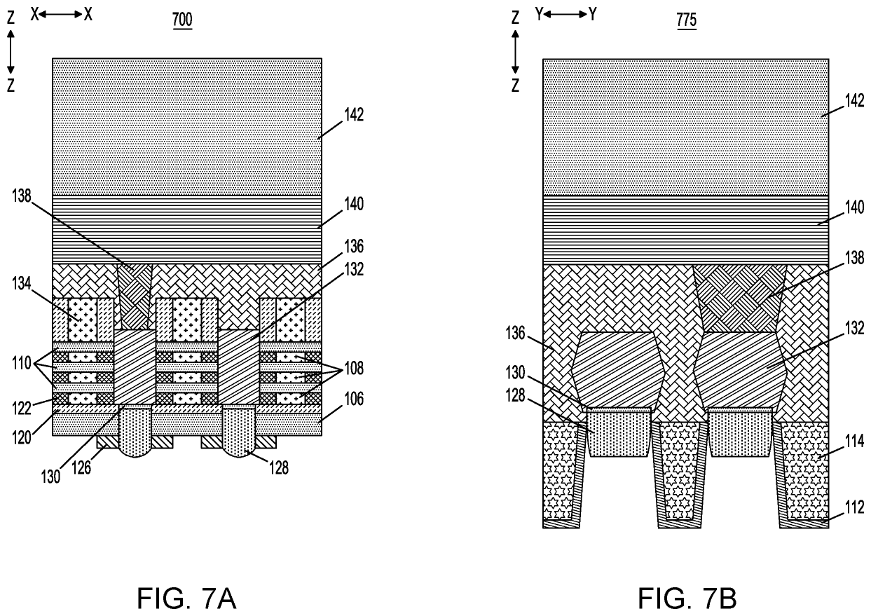

The protection liner 124 may be formed on sidewalls of the gate spacers, the nanosheet channel layers 110 and the inner spacers 122 above the BDI layer. The protection liner 124 may be formed of SiN or another suitable material such as SiCOH, SiNCH, etc. The protection liner 124 may have a thickness (in direction X) in the range of 1-3 nm. Following formation of the protection liner 124, etching is performed to open the BDI layer and form the placeholder cavity trenches 201 through the substrate 106, the etch stop layer 104 and a portion of the substrate 102. The placeholder cavity trenches 201 may be formed to a depth 203 (in direction Z) in the substrate 102 in the range of 50-70 nm. The depth 203 is selected such that during a directional etch of the etch stop layer 104 (discussed in further detail below with respect to FIGS. 7A and 7B), sufficient placeholder material remains in the placeholder cavity trenches 201.

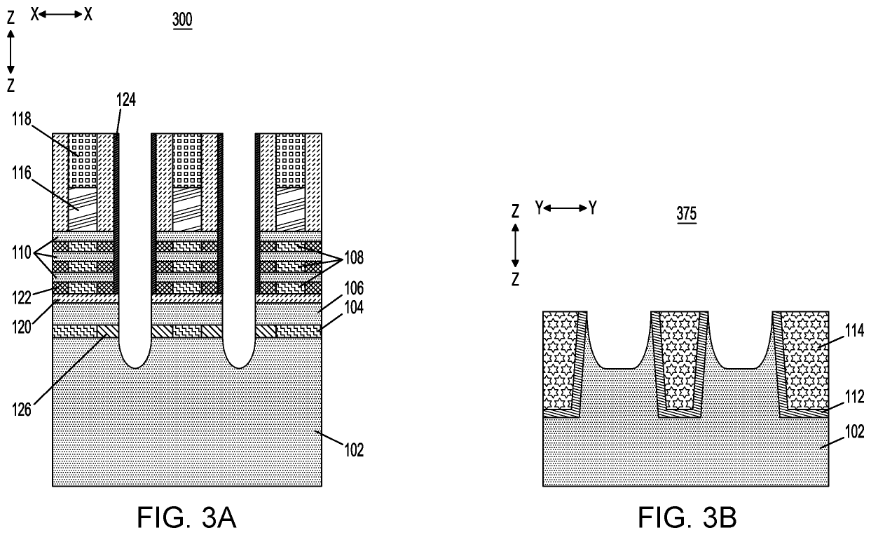

FIGS. 3A and 3B show first and second cross-sectional views 300 and 375, respectively, of the structure of FIGS. 2A and 2B following a lateral etch of the etch stop layer 104 and formation of placeholder sidewall spacers 126. The first cross-sectional view 300 of FIG. 3A is taken along the line A-A shown in the top-down view 185 of FIG. 1C, and the second cross-sectional view 375 of FIG. 3B is taken along the line B-B shown in the top-down view 185 of FIG. 1C.

The lateral etch performs indents in the etch stop layer 104, where the indents may have a depth (in direction X) in the range of 5-7 nm. The placeholder sidewall spacers 126 are then filled in the indents. The placeholder sidewall spacers 126 may be formed of a nitride-based material, such as SiN, SiCN, etc. The material for the placeholder sidewall spacers 126 may be formed using spacer pinch-off processing.

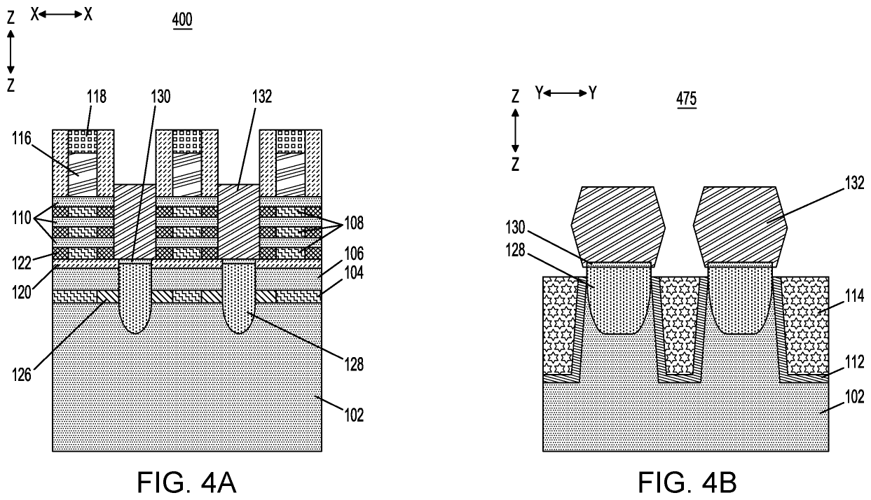

FIGS. 4A and 4B show first and second cross-sectional views 400 and 475, respectively, of the structure of FIGS. 3A and 3B following formation of placeholders 128 in the placeholder cavity trenches 201, removal of the protection liner 124, and formation of a silicon layer 130 and source/drain regions 132. The first cross-sectional view 400 of FIG. 4A is taken along the line A-A shown in the top-down view 185 of FIG. 1C, and the second cross-sectional view 475 of FIG. 4B is taken along the line B-B shown in the top-down view 185 of FIG. 1C.

The placeholders 128 may be formed by deposition of a placeholder material such as SiGe in the placeholder cavity trenches 201. The placeholder material may be planarized (e.g., using chemical mechanical planarization (CMP) or other suitable processing) such that the placeholders 128 have a top surface below that of the top surface of the BDI layer and at or above the top surface of the substrate 106. The silicon layer 130 is then epitaxially grown. The silicon layer 130 may have a height (in direction Z) in the range of 3-5 nm. The protection liner 124 is then removed (e.g., using suitable etch processing), followed by the formation of the source/drain regions 132.

The source/drain regions 132 may be formed using an epitaxial growth process. The source/drain regions 132 may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). The source/drain regions 132 may be formed by an epitaxial growth process. In some embodiments, the epitaxy process comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm³, or preferably between 2×10²⁰ cm⁻³ to 3×10²¹ cm⁻³.

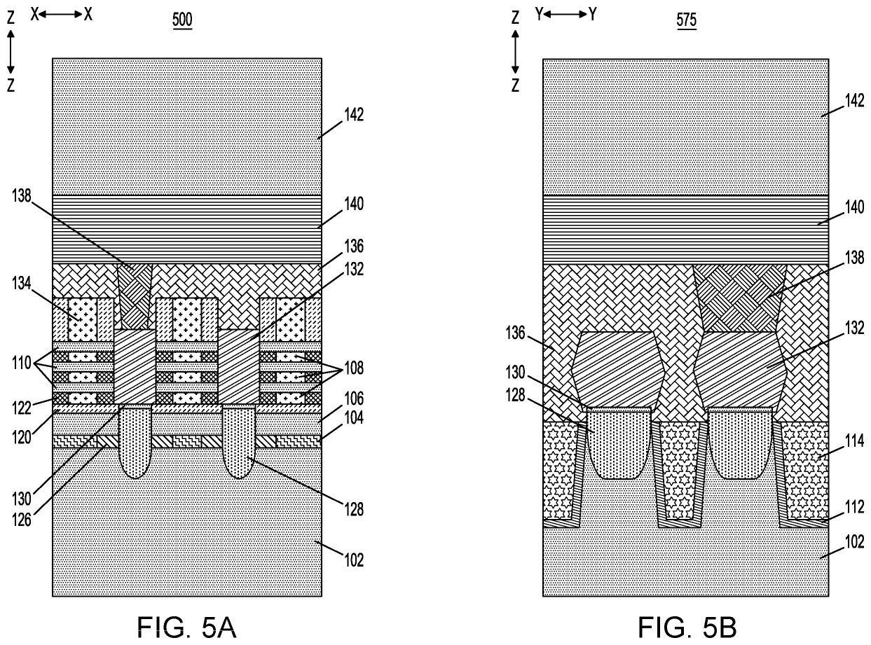

FIGS. 5A and 5B show first and second cross-sectional views 500 and 575, respectively, of the structure of FIGS. 4A and 4B following replacement metal gate (RMG) processing to form gate stack 134, formation of an interlayer dielectric (ILD) layer 136, formation of middle-of-line (MOL) contact 138, formation of back-end-of-line (BEOL) interconnects 140, and bonding to a carrier wafer 142. The first cross-sectional view 500 of FIG. 5A is taken along the line A-A shown in the top-down view 185 of FIG. 1C, and the second cross-sectional view 575 of FIG. 5B is taken along the line B-B shown in the top-down view 185 of FIG. 1C.

The RMG processing includes removal of the hard mask layer 118, the dummy gate layer 116 and the sacrificial layers 108, followed by formation of the gate stack 134. The gate stack 134 may include a gate dielectric and a gate conductor. The gate dielectric may be conformally deposited in the structure, and may be formed of a high-k material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric may have a uniform thickness in the range of 1 nm to 3 nm. The gate conductor may include a gate work function metal (WFM) layer and a gate metal layer. The gate WFM layer may be formed of a WFM such as titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. The gate WFM layer may have a uniform thickness in the range of 1 to 10 nm. The gate metal layer may comprise a conductive metal (e.g., tungsten (W)).

The ILD layer 136 may be formed of any suitable isolating material, such as SiO₂, SiOC, SiON, etc. The ILD layer 136 may have a thickness (in direction Z) in the range of 150-250 nm.

The MOL contact 138 is formed by patterning a mask layer over the ILD layer 136, etching the ILD layer 136 to form a contact trench, and filling the contact trench with a contact material (e.g., a silicide liner such as titanium (Ti), nickel (Ni), a nickel-platinum alloy (NiPt), a metal adhesion layer such as titanium nitride (TiN), and a low resistance metal fill such as tungsten (W), cobalt (Co), or ruthenium (Ru)).

The BEOL interconnects 140 are then formed over the ILD layer 136 and the MOL contact 138. The BEOL interconnects 140 may include one or more via and metallization layers or levels for forming a desired set of interconnections in the structure.

The structure is then bonded to a carrier wafer 142, which may be formed of Si or another material similar to that used for the substrates 102 and 106.

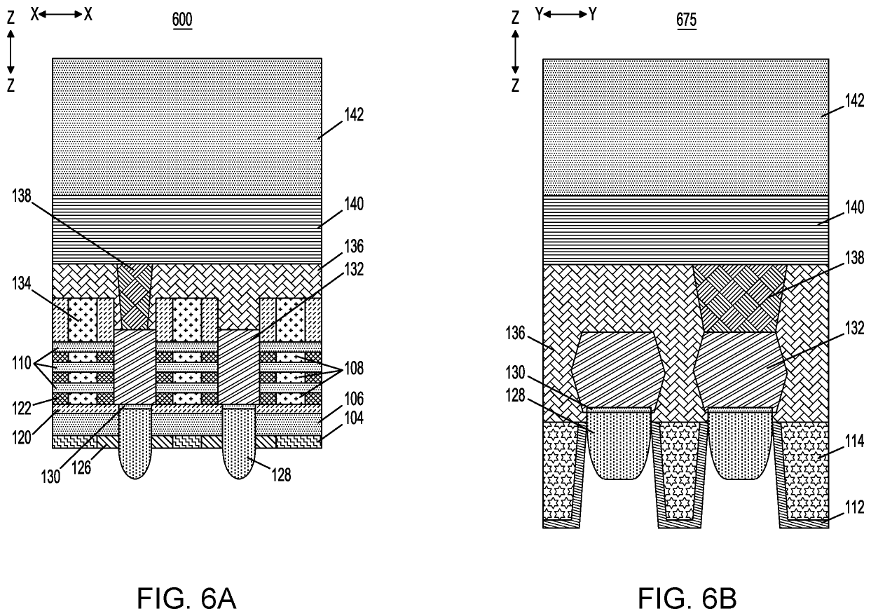

FIGS. 6A and 6B show first and second cross-sectional views 600 and 675, respectively, of the structure of FIGS. 5A and 5B following a wafer flip and removal of the substrate 102. The first cross-sectional view 600 of FIG. 6A is taken along the line A-A shown in the top-down view 185 of FIG. 1C, and the second cross-sectional view 675 of FIG. 6B is taken along the line B-B shown in the top-down view 185 of FIG. 1C.

The structure is flipped using the carrier wafer 142, followed by an etch process (e.g., RIE) which removes the substrate 102. This etch process stops at the etch stop layer 104. The etch process removes the material of the substrate 102 (e.g., Si) selective to the material of the etch stop layer 104 and the placeholders 128 (e.g., SiGe).

FIGS. 7A and 7B show first and second cross-sectional views 700 and 775, respectively, of the structure of FIGS. 6A and 6B following removal of the etch stop layer 104. The first cross-sectional view 700 of FIG. 7A is taken along the line A-A shown in the top-down view 185 of FIG. 1C, and the second cross-sectional view 775 of FIG. 7B is taken along the line B-B shown in the top-down view 185 of FIG. 1C.

The etch stop layer 104 may be removed using a directional etch process (e.g., a directional SiGe etch). This etch process will remove the etch stop layer 104, as well as a portion of the material of the placeholders 128 as illustrated.

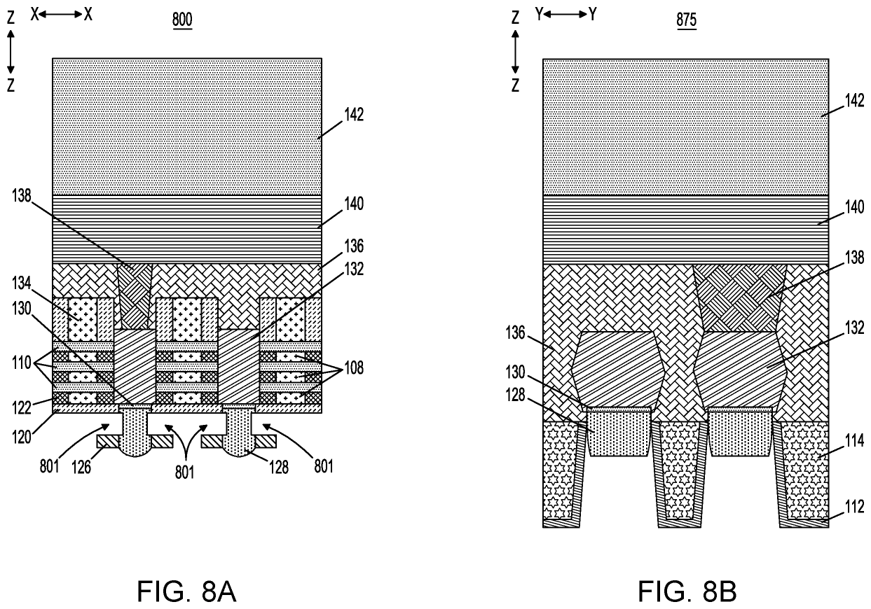

FIGS. 8A and 8B show first and second cross-sectional views 800 and 875, respectively, of the structure of FIGS. 7A and 7B following removal of the substrate 106. The first cross-sectional view 800 of FIG. 8A is taken along the line A-A shown in the top-down view 185 of FIG. 1C, and the second cross-sectional view 875 of FIG. 8B is taken along the line B-B shown in the top-down view 185 of FIG. 1C.

The substrate 106 may be removed using an etch process which removes the material of the substrate 106 (e.g., Si) selective to that of the placeholders 128. It should be noted, however, that this etch process may result in some damage or removal of parts of the material of the placeholders 128 (e.g., as shown by the indents 801). Advantageously, the placeholder sidewall spacers 126 prevent damage to the tips of the placeholders 128 (e.g., such that the tips of the placeholders 128 surrounded by the placeholder sidewall spacers 126 are wider than the portions of the placeholders 128 between the BDI layer and the placeholder sidewall spacers 126). The depth (in direction X) of the indents 801 in the placeholders 128 may be in the range of 2-3 nm, mostly as a result of over-etching.

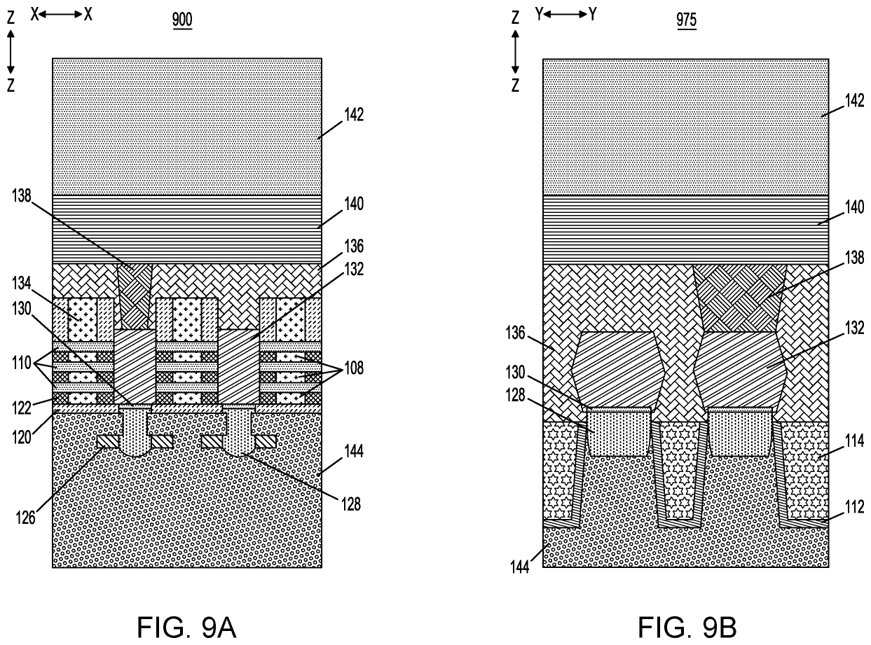

FIGS. 9A and 9B show first and second cross-sectional views 900 and 975, respectively, of the structure of FIGS. 8A and 8B following formation of a backside ILD layer 144. The first cross-sectional view 900 of FIG. 9A is taken along the line A-A shown in the top-down view 185 of FIG. 1C, and the second cross-sectional view 975 of FIG. 9B is taken along the line B-B shown in the top-down view 185 of FIG. 1C.

The backside ILD layer 144 is filled and planarized (e.g., using CMP). The backside ILD layer 144 may be filled using a conformal oxide fill, followed by chemical vapor deposition (CVD) or another suitable deposition process. The backside ILD layer 144 may be formed of similar materials as the ILD layer 136, and may have a height (in direction Z) in the range of 150-300 nm.

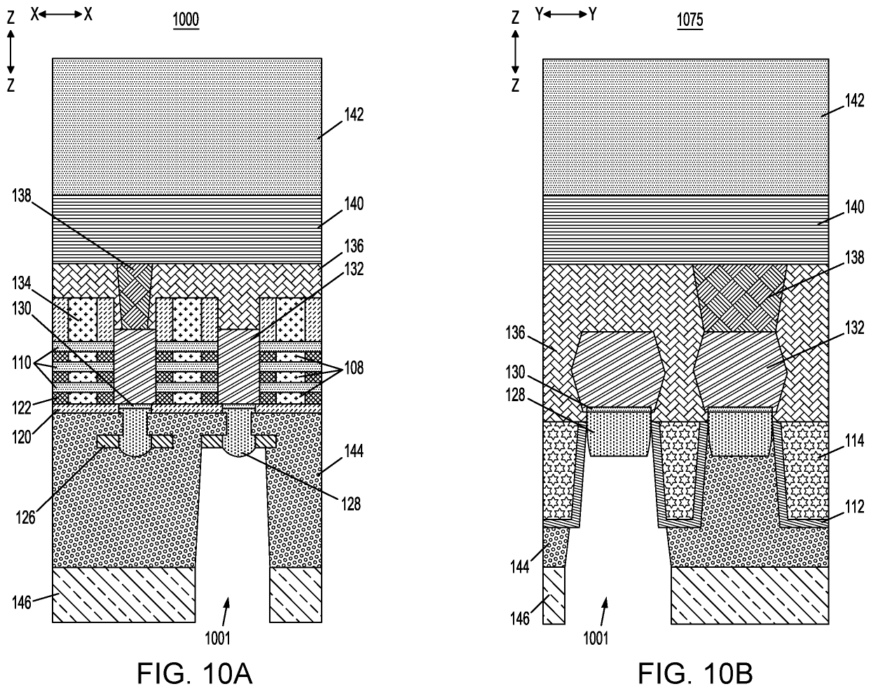

FIGS. 10A and 10B show first and second cross-sectional views 1000 and 1075, respectively, of the structure of FIGS. 9A and 9B following formation and patterning of an organic planarization layer (OPL) 146, and etching of the backside ILD layer 144 to form backside contact trench 1001. The first cross-sectional view 1000 of FIG. 10A is taken along the line A-A shown in the top-down view 185 of FIG. 1C, and the second cross-sectional view 1075 of FIG. 10B is taken along the line B-B shown in the top-down view 185 of FIG. 1C.

The OPL 146 is formed and patterned to leave openings where the backside contact trench 1001 will be formed. The backside ILD layer 144 is then etched (e.g., using RIE) to form the backside contact trench 1001. Advantageously, the placeholder sidewall spacers 126 can serve as a backside contact etch stop layer.

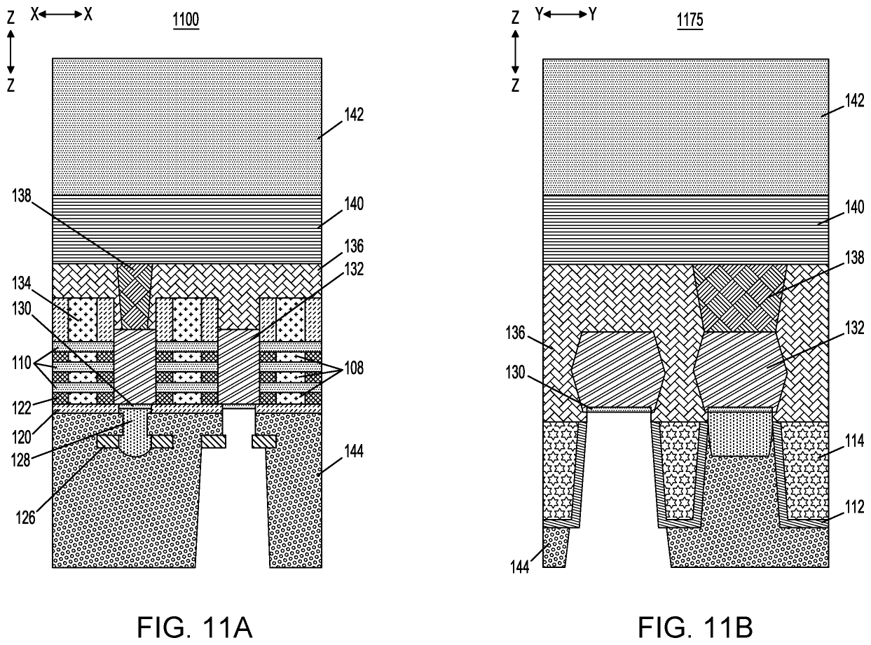

FIGS. 11A and 11B show first and second cross-sectional views 1100 and 1175, respectively, of the structure of FIGS. 10A and 10B following removal of the OPL 146 and the exposed placeholders 128. The first cross-sectional view 1100 of FIG. 11A is taken along the line A-A shown in the top-down view 185 of FIG. 1C, and the second cross-sectional view 1175 of FIG. 11B is taken along the line B-B shown in the top-down view 185 of FIG. 1C.

The OPL 146 and the exposed placeholders 128 may be removed using any suitable etch processing while the placeholder sidewall spacers 126 remain. The removal of the exposed placeholders 128 exposes the silicon layer 130 below one of the source/drain regions 132.

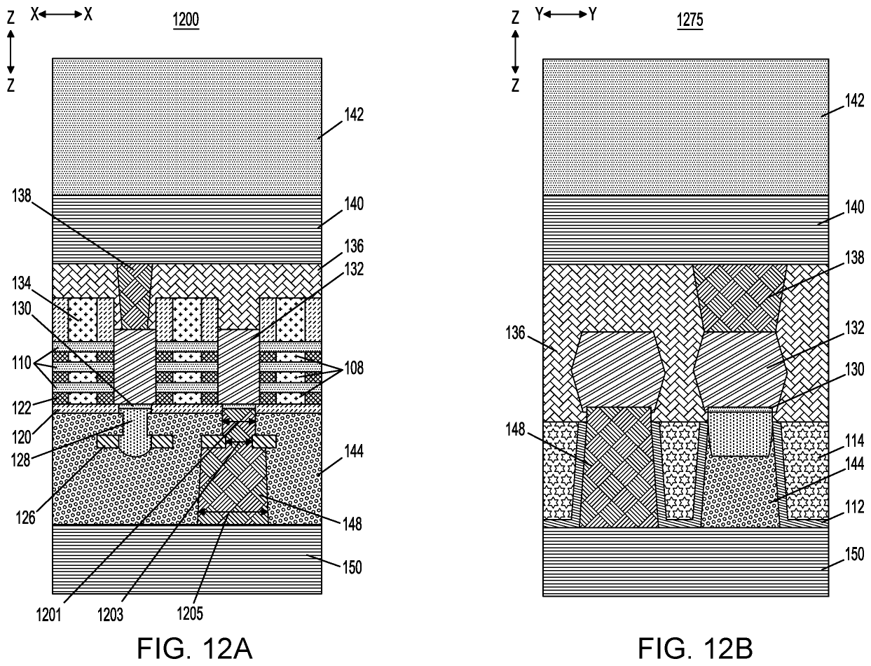

FIGS. 12A and 12B show first and second cross-sectional views 1200 and 1275, respectively, of the structure of FIGS. 11A and 11B following an optional removal of the exposed silicon layer 130, and following formation of a backside contact 148 and a backside power delivery network (BSPDN) 150. The first cross-sectional view 1200 of FIG. 12A is taken along the line A-A shown in the top-down view 185 of FIG. 1C, and the second cross-sectional view 1275 of FIG. 12B is taken along the line B-B shown in the top-down view 185 of FIG. 1C.

The exposed silicon layer 130 is optionally removed, though this is not a requirement. Backside contact metallization for the backside contact 148 is then performed (e.g., fill of the backside contact trench 1001 with contact material similar to that used for the MOL contact 138). The BSPDN 150 is then formed. The backside contact 148 has a first width 1201 “above” the upper surface of the placeholder sidewall spacers 126, a second width 1203 between the upper and lower surfaces of the placeholder sidewall spacers 126, and a third width 1205 below the lower surface of the placeholder sidewall spacers 126. The first width 1201 is greater than the second width 1203 and less than the third width 1205.

The structure shown in FIGS. 12A-12D has a first side (e.g., a frontside) and a second side (e.g., a backside) opposite the first side. The BEOL interconnects 140 are at the first or frontside of the structure, while the BSPDN 150 is at the second or backside of the structure. References to the frontside or backside surfaces of different layers or other components of the structure refer to the surface which is closest to the frontside or backside of the structure.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductor (CMOS) transistors, metal-oxide-semiconductor field-effect transistors (MOSFETs), and/or fin field-effect transistors (FinFETs). By way of non-limiting example, the semiconductor devices can include, but are not limited to CMOS, MOSFET, and FinFET devices, and/or semiconductor devices that use CMOS, MOSFET, and/or FinFET technology.

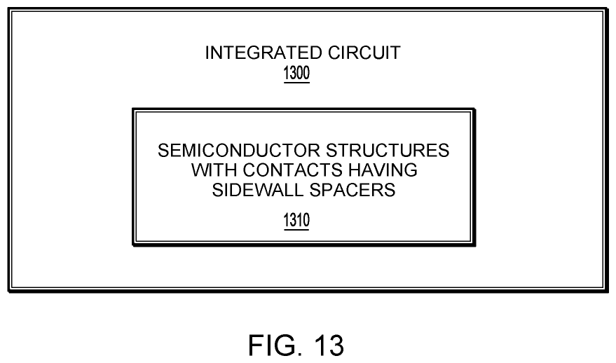

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 13 shows an example integrated circuit 1300 which includes one or more semiconductor structures 1310 with contacts having sidewall spacers.

In some embodiments, a semiconductor structure includes a transistor at a first side of the semiconductor structure, a contact to the transistor at a second side of the semiconductor structure, and sidewall spacers surrounding a portion of sidewalls of the contact. The contact has a first width above the sidewall spacers and a second width below the sidewall spacers, the second width being different than the first width.

The second width may be greater than the first width.

The contact may have a third width between upper and lower surfaces of the sidewall spacers, the third width being different than the first width and the second width. The first width may be greater than the third width, and the second width may be greater than the first width.

The contact may connect to a source/drain region of the transistor. The semiconductor structure may further include a placeholder at the second side of the semiconductor structure directly below another source/drain region of the transistor, and additional sidewall spacers surrounding a portion of sidewalls of the placeholder. The placeholder may have a third width above an upper surface of the additional sidewall spacers and a fourth width below the upper surface of the additional sidewall spacers, the third width being different than the fourth width. The fourth width may be greater than the third width.

The semiconductor structure may further include an ILD layer disposed between an upper surface of the sidewall spacers and a BDI layer of the transistor.

In some embodiments, a semiconductor structure includes a transistor at a first side of the semiconductor structure, a placeholder self-aligned to a source/drain region of the transistor at a second side of the semiconductor structure, and sidewall spacers surrounding a portion of sidewalls of the placeholder. The placeholder has a first width above an upper surface of the sidewall spacers and a second width below the upper surface of the sidewall spacers, the second width being different than the first width.

The second width may be greater than the first width.

The semiconductor structure may further include a contact to another source/drain region of the transistor at the second side of the semiconductor structure and additional sidewall spacers surrounding a portion of sidewalls of the contact, where the contact has a third width above the additional sidewall spacers and a fourth width below the additional sidewall spacers, the third width being different than the fourth width. The fourth width may be greater than the third width.

In some embodiments, a semiconductor structure includes a transistor disposed at a first side of the semiconductor structure, a placeholder at a second side of the semiconductor structure, the placeholder being self-aligned to a first source/drain region of the transistor, a contact to a second source/drain region of the transistor at the second side of the semiconductor structure, and sidewall spacers surrounding portions of sidewalls of the placeholder and the contact. A first portion of the placeholder above an upper surface of the sidewall spacers has a different width than a second portion of the placeholder below the upper surface of the sidewall spacers. A first portion of the contact above the upper surface of the sidewall spacers has a different width than a second portion of the contact below a lower surface of the sidewall spacers.

The first portion of the placeholder above the upper surface of the sidewall spacers may have a smaller width than the second portion of the placeholder below the upper surface of the sidewall spacers.

The first portion of the contact above the upper surface of the sidewall spacers may have a smaller width than the second portion of the contact below the lower surface of the sidewall spacers. A third portion of the contact between the upper and lower surfaces of the sidewall spacers may have a different width than the first portion of the contact above the upper surface of the sidewall spacers and the second portion of the contact below the lower surface of the sidewall spacers.

The upper surface of the sidewall spacers may be separated from a BDI of the transistor by an ILD layer.

In some embodiments, a transistor structure includes a first source/drain region, a second source/drain region, a placeholder self-aligned to a backside of the first source/drain region, a contact to a backside of the second source/drain region, and sidewall spacers surrounding portions of sidewalls of the placeholder and the contact. A first portion of the placeholder above an upper surface of the sidewall spacers has a different width than a second width of the placeholder below the upper surface of the sidewall spacers. A first portion of the contact above the upper surface of the sidewall spacers has a different width than a second portion of the contact below a lower surface of the sidewall spacers.

The first portion of the placeholder above the upper surface of the sidewall spacers may have a smaller width than the second portion of the placeholder below the upper surface of the sidewall spacers.

The first portion of the contact above the upper surface of the sidewall spacers may have a smaller width than the second portion of the contact below the lower surface of the sidewall spacers.

The upper surface of the sidewall spacers may be separated from a BDI layer of the transistor structure by an ILD layer.

In some embodiments, an integrated circuit includes a semiconductor structure including a transistor at a first side of the semiconductor structure, a contact to the transistor at a second side of the semiconductor structure, and sidewall spacers surrounding a portion of sidewalls of the contact. The contact has a first width above the sidewall spacers and a second width below the sidewall spacers, the second width being different than the first width.

The second width may be greater than the first width.

The contact may connect to a source/drain region of the transistor. The semiconductor structure may further include a placeholder at the second side of the semiconductor structure directly below another source/drain region of the transistor and additional sidewall spacers surrounding a portion of sidewalls of the placeholder, where the placeholder has a third width above an upper surface of the additional sidewall spacers and a fourth width below the upper surface of the additional sidewall spacers, the third width being different than the fourth width.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a transistor at a first side of the semiconductor structure;
a contact to the transistor at a second side of the semiconductor structure; and
sidewall spacers surrounding a portion of sidewalls of the contact;
wherein the contact has a first width above the sidewall spacers and a second width below the sidewall spacers, the second width being different than the first width.

2. The semiconductor structure of claim 1, wherein the second width is greater than the first width.

3. The semiconductor structure of claim 1, wherein the contact has a third width between upper and lower surfaces of the sidewall spacers, the third width being different than the first width and the second width.

4. The semiconductor structure of claim 3, wherein the first width is greater than the third width, and wherein the second width is greater than the first width.

5. The semiconductor structure of claim 1, wherein the contact connects to a source/drain region of the transistor.

6. The semiconductor structure of claim 5, further comprising:
a placeholder at the second side of the semiconductor structure directly below another source/drain region of the transistor; and
additional sidewall spacers surrounding a portion of sidewalls of the placeholder;
wherein the placeholder has a third width above an upper surface of the additional sidewall spacers and a fourth width below the upper surface of the additional sidewall spacers, the third width being different than the fourth width.

7. The semiconductor structure of claim 6, wherein the fourth width is greater than the third width.

8. The semiconductor structure of claim 6, wherein the additional sidewall spacers surrounding the portion of the sidewalls of the placeholder are vertically aligned with the sidewall spacers surrounding the portion of the sidewalls of the contact.

9. A semiconductor structure, comprising:
a transistor at a first side of the semiconductor structure;
a placeholder self-aligned to a source/drain region of the transistor at a second side of the semiconductor structure; and
sidewall spacers surrounding a portion of sidewalls of the placeholder;
wherein the placeholder has a first width above an upper surface of the sidewall spacers and a second width below the upper surface of the sidewall spacers, the second width being different than the first width.

10. The semiconductor structure of claim 9, wherein the second width is greater than the first width.

11. The semiconductor structure of claim 9, further comprising:
a contact to another source/drain region of the transistor at the second side of the semiconductor structure; and
additional sidewall spacers surrounding a portion of sidewalls of the contact;
wherein the contact has a third width above the additional sidewall spacers and a fourth width below the additional sidewall spacers, the third width being different than the fourth width.

12. The semiconductor structure of claim 11, wherein the fourth width is greater than the third width.

13. A semiconductor structure, comprising:
a transistor disposed at a first side of the semiconductor structure;
a placeholder at a second side of the semiconductor structure, the placeholder being self-aligned to a first source/drain region of the transistor;
a contact to a second source/drain region of the transistor at the second side of the semiconductor structure; and
sidewall spacers surrounding portions of sidewalls of the placeholder and the contact;
wherein a first portion of the placeholder above an upper surface of the sidewall spacers has a different width than a second portion of the placeholder below the upper surface of the sidewall spacers; and
wherein a first portion of the contact above the upper surface of the sidewall spacers has a different width than a second portion of the contact below a lower surface of the sidewall spacers.

14. The semiconductor structure of claim 13, wherein the first portion of the placeholder above the upper surface of the sidewall spacers has a smaller width than the second portion of the placeholder below the upper surface of the sidewall spacers.

15. The semiconductor structure of claim 13, wherein the first portion of the contact above the upper surface of the sidewall spacers has a smaller width than the second portion of the contact below the lower surface of the sidewall spacers.

16. The semiconductor structure of claim 15, wherein a third portion of the contact between the upper and lower surfaces of the sidewall spacers has a different width than the first portion of the contact above the upper surface of the sidewall spacers and the second portion of the contact below the lower surface of the sidewall spacers.

17. The semiconductor structure of claim 13, wherein the upper surface of the sidewall spacers is separated from a bottom dielectric insulator layer of the transistor by an interlayer dielectric layer.

18. A transistor structure, comprising:
a first source/drain region;
a second source/drain region;
a placeholder self-aligned to a backside of the first source/drain region;
a contact connected to a backside of the second source/drain region; and
sidewall spacers surrounding portions of sidewalls of the placeholder and the contact;
wherein a first portion of the placeholder above an upper surface of the sidewall spacers has a different width than a second width of the placeholder below the upper surface of the sidewall spacers; and
wherein a first portion of the contact above the upper surface of the sidewall spacers has a different width than a second portion of the contact below a lower surface of the sidewall spacers.

19. The transistor structure of claim 18, wherein the first portion of the placeholder above the upper surface of the sidewall spacers has a smaller width than the second portion of the placeholder below the upper surface of the sidewall spacers.

20. The transistor structure of claim 18, wherein the first portion of the contact above the upper surface of the sidewall spacers has a smaller width than the second portion of the contact below the lower surface of the sidewall spacers.

21. The transistor structure of claim 18, wherein the upper surface of the sidewall spacers is separated from a bottom dielectric insulator layer of the transistor structure by an interlayer dielectric layer.

22. An integrated circuit comprising:
a semiconductor structure comprising:
a transistor at a first side of the semiconductor structure;
a contact to the transistor at a second side of the semiconductor structure; and
sidewall spacers surrounding a portion of sidewalls of the contact;
wherein the contact has a first width above the sidewall spacers and a second width below the sidewall spacers, the second width being different than the first width.

23. The integrated circuit of claim 22, wherein the second width is greater than the first width.

24. The integrated circuit of claim 22, wherein the contact connects to a source/drain region of the transistor.

25. The integrated circuit of claim 24, wherein the semiconductor structure further comprises a placeholder at the second side of the semiconductor structure directly below another source/drain region of the transistor and additional sidewall spacers surrounding a portion of sidewalls of the placeholder, and wherein the placeholder has a third width above an upper surface of the additional sidewall spacers and a fourth width below the upper surface of the additional sidewall spacers, the third width being different than the fourth width.
